(19) United States
(12) Patent Application Publication
(10) Pub. No.: US 2024/0234357 A1
(43) Pub. Date: Jul. 11, 2024

(54) ELECTRONIC DEVICE AND METHOD OF MANUFACTURING THE SAME

(71) Applicant: Samsung Display Co., Ltd., Yongin-si (KR)

(72) Inventors: JEONGWEON SEO, Yongin-si (KR); MANSOO KIM, Yongin-si (KR); MYUNGCHUL KIM, Yongin-si (KR); SEUNG-SOO RYU, Yongin-si (KR); SANGHYUCK YOON, Yongin-si (KR)

(73) Assignee: Samsung Display Co., Ltd., Yongin-si (KR)

(21) Appl. No.: 18/404,110

(22) Filed: Jan. 4, 2024

(30) Foreign Application Priority Data
Jan. 9, 2023 (KR) 10-2023-0002950

(51) Int. Cl. H01L 23/00; H10K 59/131

(52) U.S. Cl. CPC H01L 24/13; H01L 24/11; H01L 24/16; H01L 24/32; H01L 24/73; H01L 24/81; H01L 24/83; H01L 24/92; H10K 59/131; H01L 2224/1162; H01L 2224/13007; H01L 2224/1319; H01L 2224/13562; H01L 2224/13566; H01L 2224/13578; H01L 2224/13582; H01L 2224/13624; H01L 2224/13666; H01L 2224/16227; H01L 2224/32225; H01L 2224/73204; H01L 2224/81201; H01L 2224/83201; H01L 2224/9211

(57) ABSTRACT

Provided is an electronic device including a display panel including pixels, and first pads respectively including pad parts which are disposed in one direction and respectively electrically connected to the pixels, and conductive members electrically connected to the pad parts, a circuit board including second pads disposed in the one direction and respectively electrically connected to the first pads, and an adhesive layer disposed between the display panel and the circuit board. The conductive members each include a first member disposed on the pad part and having an insulation property, a second member covering the first member and connected to the pad part, and a third member disposed on the second member while exposing a portion of the second member and including a material different from a material of the second member.

### CROSS-REFERENCE TO RELATED APPLICATIONS

This application claims priority to and benefits of Korean Patent Application No. 10-2023-0002950 under 35 U.S.C. § 119, filed on Jan. 9, 2023 in the Korean Intellectual Property Office, the entire contents of which are incorporated herein by reference.

### BACKGROUND

### 1. Technical Field

The disclosure herein relates to an electronic device, and, to an electronic device including electrically connected electronic components.

### 2. Description of the Related Art

Various electronic devices used for multi-media devices such as a television, a mobile phone, a tablet computer, a navigation system, and a game console are being developed. Such electronic devices include electronic components. Electronic components may include a display panel, a driver chip, a circuit board, and the like. Such electronic components are electrically connected in various manners.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides an electronic device with improved electrical bonding reliability and a method of manufacturing an electronic device with improved bonding reliability.

An embodiment provides an electronic device that may include a display panel including pixels, and first pads respectively including pad parts disposed in one direction and respectively connected to the pixels; and conductive members electrically connected to the pad parts; a circuit board including second pads disposed in the one direction and respectively electrically connected to the first pads; and an adhesive layer disposed between the display panel and the circuit board, wherein the conductive members each include a first member disposed on the pad part and having an insulation property; a second member covering the first member and connected to the pad part, and a third member disposed on the second member while exposing a portion of the second member and including a material different from a material of the second member.

In an embodiment, the second member may include a first portion covered by the third member, and a second portion exposed from the third member, and the second portion may directly contact the second pads.

In an embodiment, the third member may be disposed between the adhesive layer and the second member.

In an embodiment, a thickness of the third member may be less than a thickness of the second member, and a thickness ratio of the third member to the second member may be about ⅙ or less.

In an embodiment, the third member may have a thickness in a range of about 100 Å to about 400 Å.

In an embodiment, each of the conductive members may include a sub member disposed between the second member and the third member.

In an embodiment, the electronic device may further include at least one pattern disposed on the second portion of the second member.

In an embodiment, an electronic device may include a display panel including pixels, and first pads respectively including pad parts disposed in one direction and respectively connected to the pixels, and conductive members connected to the pad parts; a circuit board including second pads disposed in the one direction and respectively electrically connected to the first pads; and an adhesive layer disposed between the display panel and the circuit board, wherein the conductive members each include a first member disposed on the pad part and having an insulation property, a second member covering the first member and connected to the pad part, a third member disposed on the second member and including a material different from a material of the second member, and conductive particles electrically connecting the second pad to the second member while overlapping the third member in a plan view, and a portion of at least one of the conductive particles passes through the third member and directly contacts the second member.

In an embodiment, the electronic device may further include a sub pad covering the second pad and contacting each of the second pads and the conductive particles.

In an embodiment, another portion of at least one of the conductive particles may pass through the sub pad.

In an embodiment, the sub pad may include a curable material.

In an embodiment, the sub pad may have a recessed portion and accommodating the conductive particles.

In an embodiment, a minimum diameter of the conductive particles may be greater than a thickness of the third member.

In an embodiment, a thickness of the third member may be less than a thickness of the second member, and a thickness ratio of the third member to the second member may be about ⅙ or less.

In an embodiment, the third member may have a thickness in a range of about 100 Å to about 400 Å.

In an embodiment, the conductive member may include a sub member disposed between the second member and the third member.

In an embodiment, a method of manufacturing an electronic device, the method may include preparing a display panel including first pads including a pad part and a preliminary conductive member including a first member disposed on the pad part and having an insulation property; a second member covering the first member and connected to the pad part, and a third member disposed on the second member and including a material different from a material of the second member; forming a conductive member in which a portion of the second member is exposed by removing a portion of the third member; covering the conductive member with a resin by spraying the resin to the conductive member; preparing a circuit board including second pads respectively electrically connected to the first pads and removing the resin covering the conductive member; and electrically connecting the first pads to the second pads by pressurizing either of the circuit board or the display panel.

In an embodiment, the method may further include forming an adhesive layer on the display panel before the electrically connecting of the first pads to the second pads.

In an embodiment, the second member may include a first portion covered by the third member, and a second portion exposed from the third member, and the second portion may directly contact the second pads.

In an embodiment, the conductive member may further include at least one pattern disposed on the second portion.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1A is a schematic perspective view of an electronic device according to an embodiment;

FIG. 1B is an exploded perspective view of an electronic device according to an embodiment;

FIG. 1C is a schematic cross-sectional view of a circuit board connected to a display device according to;

FIG. 2 is a schematic cross-sectional view of a display device according to an embodiment;

FIG. 3 is a schematic plan view of a display panel according to an embodiment;

FIG. 4 is an exploded perspective view of a bonding region in an electronic device according to an embodiment;

FIGS. 5A and 5B are schematic cross-sectional views of bonded pads of a display device according to an embodiment;

FIGS. 6A to 6E are schematic cross-sectional views of bonded pads of a display device according to an embodiment;

FIGS. 7A to 7E are schematic cross-sectional views illustrating a number of operations of a method of manufacturing an electronic device according to an embodiment;

FIGS. 8A and 8B are schematic cross-sectional views illustrating a number of operations of a method of manufacturing an electronic device according to an embodiment; and

FIGS. 9A and 9B are schematic cross-sectional views illustrating a number of operations of a method of manufacturing an electronic device according to an embodiment.

### DETAILED DESCRIPTION OF THE EMBODIMENTS

The disclosure will now be described more fully hereinafter with reference to the accompanying drawings, in which embodiments are shown. This disclosure may however, be embodied in different forms and should not be construed as limited to the embodiments set forth herein. Rather, these embodiments are provided so that this disclosure will be thorough and complete, and will fully convey the scope of the disclosure to those skilled in the art.

In this specification, it will be understood that when an element (or a region, a layer, a portion, or the like) is referred to as “being on”, “connected to” or “coupled to” another element, it may be directly disposed on/connected/coupled to the other element, or intervening elements may be disposed therebetween.

It will be understood that the terms “connected to” or “coupled to” may include a physical or electrical connection or coupling.

Like reference numerals or symbols refer to like elements throughout. In the drawings, the thickness, the ratio, and the dimension of the elements are exaggerated for effective description of the technical contents.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the scope of the disclosure.

The singular forms include the plural forms as well, unless the context clearly indicates otherwise. For example, as used herein, the singular forms, “a,” “an,” and “the” are intended to include the plural forms as well, unless the context clearly indicates otherwise.

In the specification and the claims, the phrase “at least one of” is intended to include the meaning of “at least one selected from the group of” for the purpose of its meaning and interpretation. For example, “at least one of A and B” may be understood to mean “A, B, or A and B.”

The terms such as “below”, “lower”, “above”, “upper” and the like, may be used herein for the description to describe one element's relationship to another element illustrated in the figures. It will be understood that the terms have a relative concept and are described on the basis of the orientation depicted in the figures.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

It will be understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments will be described with reference to the accompanying drawings.

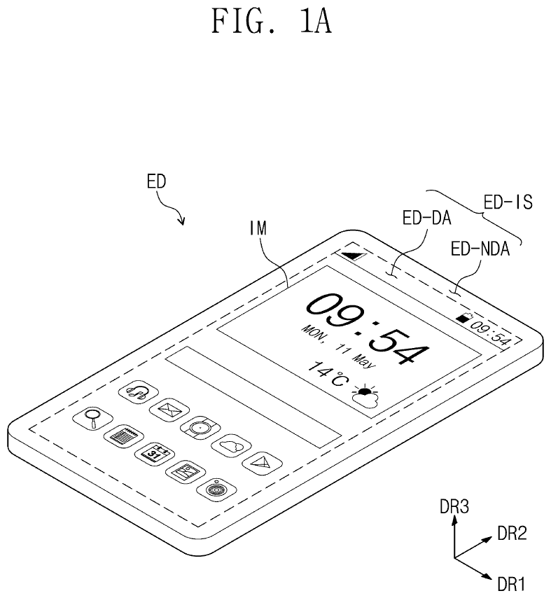

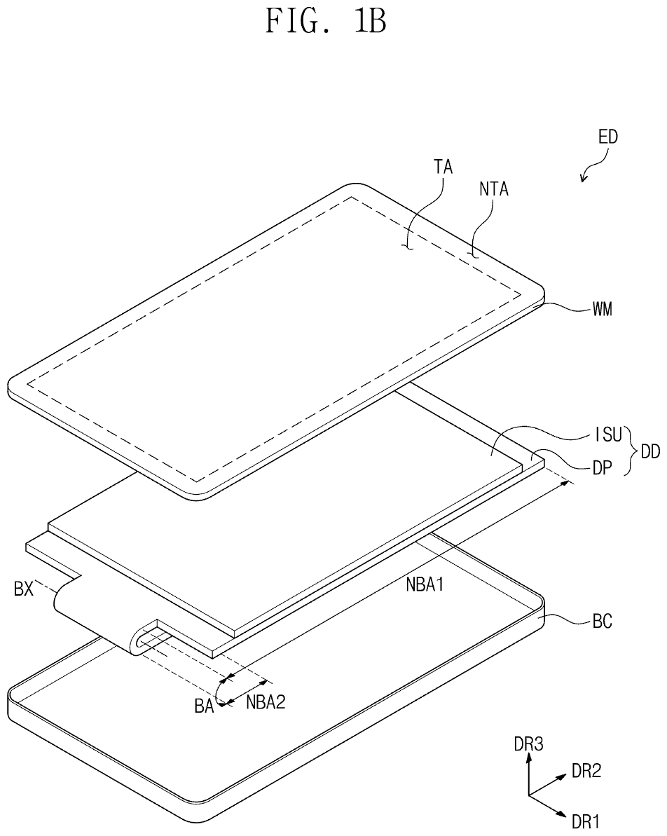

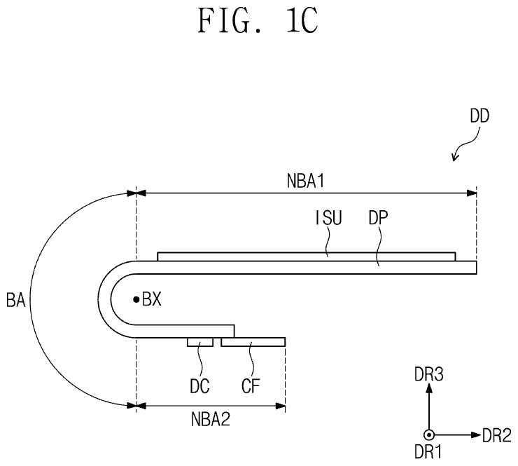

FIG. 1A is a schematic perspective view of an electronic device according to an embodiment, FIG. 1B is an exploded perspective view of an electronic device according to an embodiment, and FIG. 1C is a schematic cross-sectional view of a circuit board connected to a display device according to an embodiment.

In this specification, an electronic device ED may be illustrated as a cellular phone terminal. The electronic device ED according to the disclosure may be applied to a small- and medium-sized electronic device such as a tablet computer, a car navigation system, a game console, and a smart watch, as well as a large-sized electronic device such as a television and a monitor.

Referring to FIG. 1A, the electronic device ED may display an image IM through a display surface ED-IS. Icon images may be illustrated as the image IM. The display surface ED-IS may be parallel to a surface defined by a first direction DR1 and a second direction DR2. The normal direction of the display surface ED-IS and the thickness direction of the electronic device ED may be parallel to a third direction DR3.

The display surface ED-IS may include a display region ED-DA in which the image IM is displayed and a non-display region ED-NDA adjacent to the display region ED-DA. The non-display region ED-NDA may be a region in which an image is not displayed. However, an embodiment is not limited thereto, and the non-display region ED-NDA may be adjacent to any one side or a side of the display region ED-DA or may be omitted.

In this specification, the wording, “when viewed on a plane or on a plane” may mean a case when viewed in the third direction DR3. A front surface (or upper surface) and a rear surface (or lower surface) of each layer or unit to be described below are defined based on the third direction DR3. However, an embodiment is not limited thereto, and combinations of the first to third directions DR1, DR2, and DR3 may be changed to other combinations thereof.

Referring to FIG. 1B, the electronic device ED may include a window WM, a display device DD, and an accommodation member BC. Although not illustrated, the electronic device ED may further include an optical member disposed between the window WM and the display device DD. The optical member may include a polarizer.

The window WM may be disposed above the display device DD and transmit an image generated from the display device DD to the outside. The window WM may include a transmission region TA and a non-transmission region NTA. The transmission region TA may overlap the display region ED-DA and have a shape corresponding to the display region ED-DA. The window WM may include a base layer and functional layers disposed on the base layer. The functional layers may include a protective layer, an anti-fingerprint layer, and the like within the spirit and the scope of the disclosure. The base layer of the window WM may be composed of glass, sapphire, plastic, or the like within the spirit and the scope of the disclosure.

The non-transmission region NTA may overlap the non-display region ED-NDA and have a shape corresponding to the non-display region ED-NDA. The non-transmission region NTA may be a region having a relatively lower light transmittance than the transmission region TA. The non-transmission region NTA may be defined by disposing a bezel pattern in a partial region of the base layer of the window WM, and the transmission region TA may be defined as a region where the bezel pattern is not disposed. However, the disclosure is not limited thereto, and the non-transmission region NTA may be omitted.

According to an embodiment, a display panel DP may be any one among a liquid crystal display panel, an electrophoretic display panel, a microelectromechanical system (MEMS) display panel, an electrowetting display panel, an organic light-emitting display panel, an inorganic light-emitting display panel, and a quantum dot light-emitting display panel, and is not particularly limited. Hereinafter, the display panel DP may be described as an organic light-emitting display panel.

An input sensor ISU may include any one of a capacitive sensor, an optical sensor, an ultrasonic sensor, or an electromagnetic induction sensor. The input sensor ISU may be formed on the display panel DP through a continuous process or may be manufactured separately and then attached to an upper side of the display panel DP via an adhesive layer, but is not limited to any one embodiment.

The display device DD may further include a driver chip DC and a circuit board CF. In an embodiment, it is illustrated that the driver chip DC is mounted on the display panel DP but it is not limited thereto. The driver chip DC may generate a driving signal required for an operation of the display panel DP on the basis of a control signal transmitted from the circuit board CF.

The circuit board CF electrically bonded to the display panel DP may be bent and disposed on the rear surface of the display panel DP. The accommodation member BC may accommodate the display device DD and may be bonded to the window WM. The circuit board CF may be disposed on one end of a base substrate SUB and electrically connected to a circuit element layer DP-CL. Although not illustrated, the electronic device ED may further include a main board, electronic modules mounted on the main board, a camera module, a power module, and the like within the spirit and the scope of the disclosure.

Referring to FIG. 1C, the display panel DP according to an embodiment may include a bending region BA, and a first non-bending region NBA1 and a second non-bending region NBA2 which are arranged (or disposed) to be spaced apart from each other in the second direction DR2 with the bending region BA therebetween.

The bending region BA may be defined as a region in which the display panel DP is bent with respect to an imaginary bending axis BX extending in the first direction DR1. The first non-bending region NBA1 may be defined as a region overlapping the transmission region TA, and the second non-bending region NBA2 may be defined as a region to which the circuit board CF is connected.

In case that the bending region BA is bent with respect to the bending axis BX, the circuit board CF and the driver chip DC may be bent toward the rear surface of the display panel DP and disposed on the rear surface of the display panel DP.

Although not illustrated, additional components may be disposed to compensate for a step, caused by forming the bending region BA, between the rear surface of the display panel DP and the circuit board CF.

According to an embodiment, in the first direction DR1, the width of the first non-bending region NBA1 may be greater than the widths of the bending region BA and the second non-bending region NBA2. However, an embodiment is not limited thereto, and the bending region BA may be provided in a shape such that the width of the bending region BA becomes narrower from the first non-bending region NBA1 toward the second non-bending region NBA2, and the bending region BA is not limited to any one embodiment.

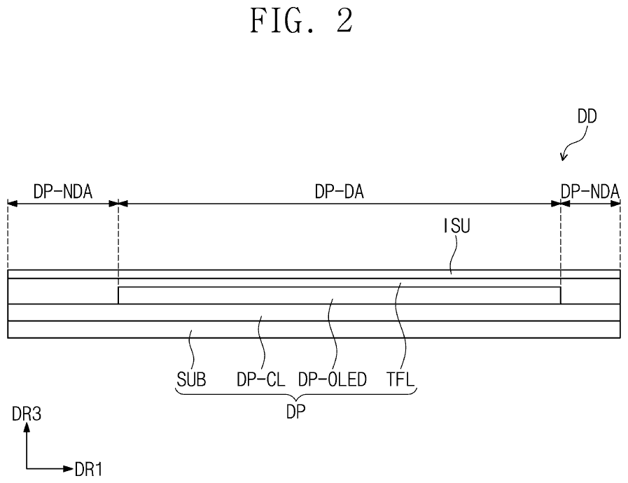

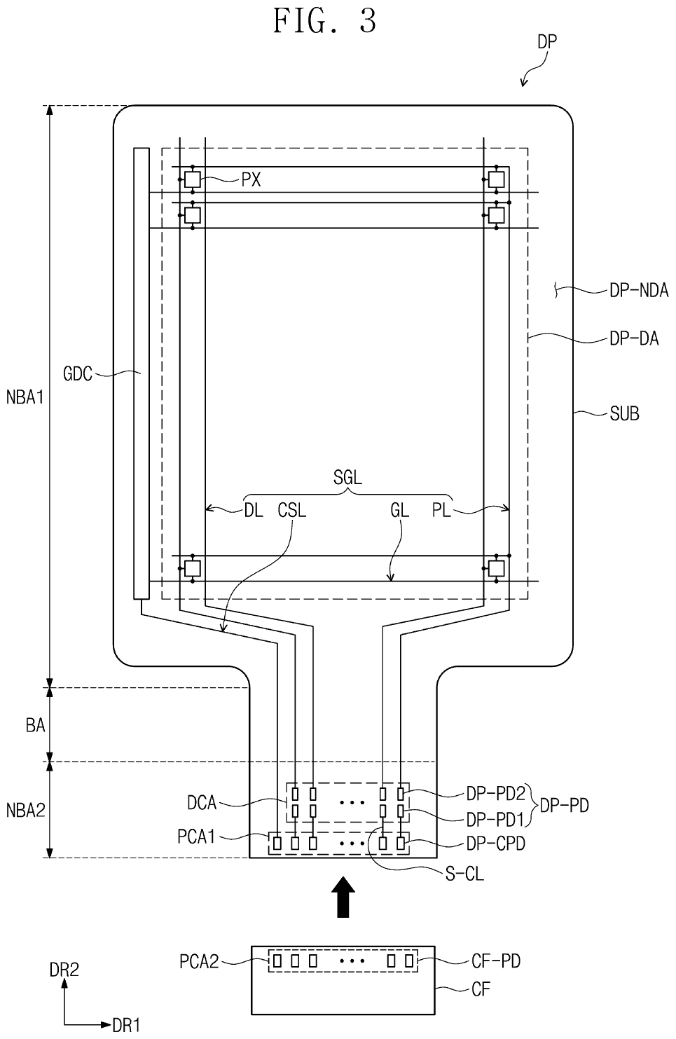

FIG. 2 is a schematic cross-sectional view of a display device according to an embodiment, and FIG. 3 is a schematic plan view of a display panel according to an embodiment.

Referring to FIG. 2, a display panel DP may include a base substrate SUB, a circuit element layer DP-CL disposed on the base substrate SUB, a display element layer DP-OLED, and an upper insulating layer TFL. An input sensor ISU may be disposed on the upper insulating layer TFL.

In FIG. 2, regions corresponding to the aforementioned bending region BA and second non-bending region NBA2 of the display panel DP in FIG. 1C are omitted.

The display panel DP may include a display region DP-DA and a non-display region DP-NDA. The display region DP-DA of the display panel DP may correspond to the display region ED-DA described in FIG. 1A or the transmission region TA described in FIG. 1B, and the non-display region DP-NDA may correspond to the non-display region ED-NDA described in FIG. 1A or the non-transmission region NTA described in FIG. 1B.

The base substrate SUB may include at least one plastic film. The base substrate SUB is a flexible substrate and may include a plastic substrate, a glass substrate, a metal substrate, an organic/inorganic composite material substrate, or the like within the spirit and the scope of the disclosure.

The display element layer DP-OLED may include organic light-emitting diodes. The display element layer DP-OLED may further include an organic layer such as a pixel-defining film. The upper insulating layer TFL seals the display element layer DP-OLED. For example, the upper insulating layer TFL may include a thin-film encapsulation layer. The thin-film encapsulation layer may include a stacked structure of an inorganic layer/an organic layer/an inorganic layer. The upper insulating layer TFL protects the display element layer DP-OLED against moisture, oxygen, and impurities such as dust particles. However, an embodiment is not limited thereto, and the upper insulating layer TFL may further include an additional insulating layer to a thin-film encapsulation layer. For example, an optical insulating layer for controlling a refractive index may be further included.

In an embodiment, an encapsulation substrate may be provided instead of the upper insulating layer TFL. The encapsulation substrate may be disposed on the display element layer DP-OLED to face the base substrate SUB. The encapsulation substrate may be more rigid than the upper insulating layer TFL. The encapsulation substrate may seal the display element layer DP-OLED while protecting the display element layer DP-OLED against an external impact.

The input sensor ISU may be directly disposed on the display panel DP. In this specification, the wording, “an A component being directly disposed on a B component” means that another component is not disposed between the A component and the B component. In this embodiment, the input sensor ISU may be manufactured on the display panel DP through a continuous process. However, the disclosure is not limited thereto, and the input sensor ISU may be provided as an individual panel and bonded to the display panel DP via the adhesive layer. As another example, the input sensor ISU may be omitted.

Referring to FIG. 3, a display panel DP may include pixels PX, a gate driving circuit GDC, signal lines SGL, and display pads DP-PD and DP-CPD.

The pixels PX are disposed in the display region DP-DA. The pixels PX each include an organic light-emitting diode and a pixel driving circuit connected thereto. The display region DP-DA may be substantially a region in which the organic light-emitting diode is disposed. Accordingly, the pixel driving circuit may be disposed in the display region DP-DA or disposed in the non-display region DP-NDA. As long as being electrically connected to the organic light-emitting diode, the pixel driving circuit may be disposed in various positions but is not limited to any one embodiment.

The gate driving circuit GDC sequentially outputs gate signals to gate lines GL. The gate driving circuit GDC may include thin-film transistors formed through the same process for a driving circuit of the pixels PX, for example, a low temperature polycrystalline silicon (LTPS) process or a low temperature polycrystalline oxide (LTPO) process. The display panel DP may further include another driving circuit providing a light emission control signal to the pixels PX.

In this embodiment, it is illustrated that the gate driving circuit GDC is disposed in the non-display region DP-NDA, but it is not limited thereto. For example, on a plane view, at least a portion of the gate driving circuit GDC may be disposed to overlap the display region DP-DA. In this embodiment, the gate driving circuit GDC is illustrated as a single gate driving circuit but may be provided in plurality. As long as being electrically connected to the pixels PX, the gate driving circuit GDC may be disposed in various positions and provided in various numbers, and is not limited to any one embodiment.

The signal lines SGL may include gate lines GL, data lines DL, a power line PL, and a control signal line CSL. The gate lines GL may be respectively connected to the corresponding pixels PX among the pixels PX, and the data lines DL may be respectively connected to the corresponding pixels PX among the pixels PX. The power line PL is connected to the pixels PX. The control signal line CSL may provide control signals to a scan driving circuit.

The signal lines SGL overlap the display region DP-DA and the non-display region DP-NDA.

The display panel DP may include display pads. The display pads may include first display pads DP-PD and second display pads DP-CPD. According to an embodiment, the first display pads DP-PD and the second display pads DP-CPD may be disposed on the second non-bending region NBA2.

A chip region DCA and a first pad region PCA1 which are spaced apart from each other may be defined in the non-display region DP-NDA. The chip region DCA may be a region to which the driver chip DC (see FIG. 1C) is coupled and in which the first display pads DP-PD are disposed, and the first pad region PCA1 may be a region to which a circuit board CF is connected and in which the second display pads DP-CPD are disposed. The first display pads DP-PD are electrically connected to the driver chip DC to transmit, to the signal lines SGL, an electrical signal received from the driver chip DC.

The first display pads DP-PD include first-row display pads DP-PD1 arranged in the first direction DR1 and second-row display pads DP-PD2 spaced apart from the first-row display pads DP-PD1 in the second direction DR2 and arranged in the first direction DR1.

The second display pads DP-CPD may be disposed in the first pad region PCA1. The second display pads DP-CPD may be arranged in the first direction DR1. The first display pads DP-PD may be respectively connected to the corresponding display pads of the second display pads DP-CPD through bridge signal lines S-CL.

Also, like the first display pads DP-PD, the second display pads DP-CPD may include row display pads arranged in the first direction DR1.

The circuit board CF may include circuit pads CF-PD arranged in the first direction DR1. The circuit pads CF-PD may be disposed in a second pad region PCA2 defined in the circuit board CF. The circuit pads CF-PD may be pads connected to the display panel DP.

Also, in case that the second display pads DP-CPD are arranged in the form of row pads arranged in the first direction DR1, the circuit pads CF-PD included in the circuit board CF may also have an arrangement form of one-to-one correspondence with the second display pads DP-CPD, and the arrangement is not limited to any one embodiment.

The second pad region PCA2 of the circuit board CF may be disposed on the first pad region PCA1. The second display pads DP-CPD may be electrically connected to the circuit pads CF-PD included in the circuit board CF to transmit, to first display pads DP-PD, an electrical signal received from the circuit board CF. The circuit board CF may be rigid or flexible. For example, in case that the circuit board CF is flexible, the circuit board CF may be provided as a flexible printed circuit board.

The circuit board CF may include a timing control circuit for controlling an operation of the display panel DP. The timing control circuit may be mounted on the circuit board CF in the form of an integrated chip. Although not illustrated, the circuit board CF may include an input detection circuit that controls the input sensor ISU.

It is illustrated that the display panel DP has a structure including the first display pads DP-PD for mounting the driver chip DC illustrated in FIG. 1B, but it is not limited thereto. The driver chip DC may be mounted on the circuit board CF, and the first display pads DP-PD may be omitted.

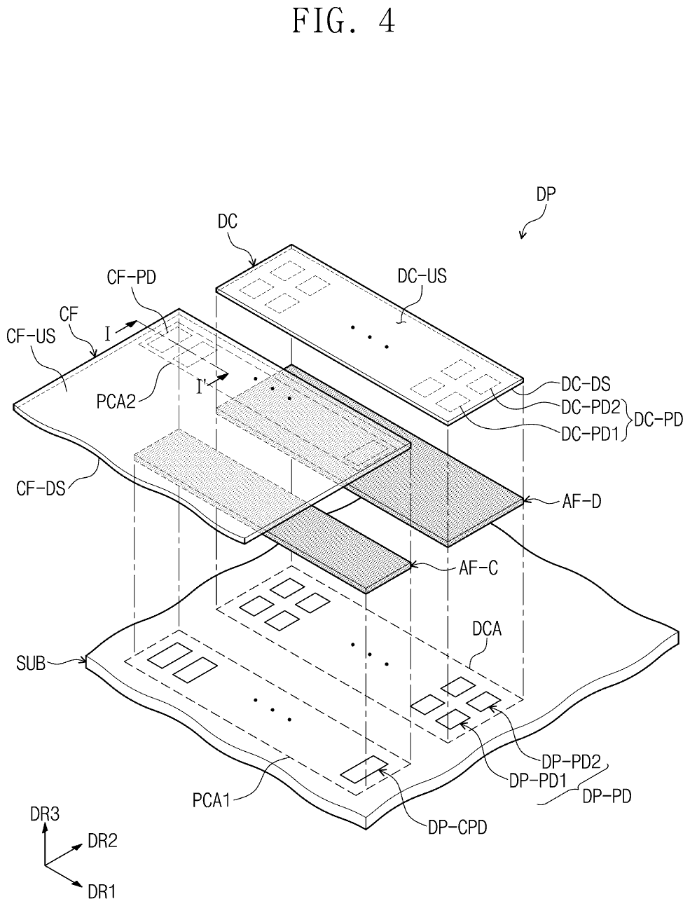

FIG. 4 is an exploded perspective view of a bonding region in an electronic device according to an embodiment.

Referring to FIG. 4, a display panel DP may include a first adhesive layer AF-C disposed between a circuit board CF and a base substrate SUB and a second adhesive layer AF-D disposed between a driver chip DC and the base substrate SUB. The first adhesive layer AF-C may connect the circuit board CF to the display panel DP, and the second adhesive layer AF-D may connect the driver chip DC to the display panel DP. The first adhesive layer AF-C and the second adhesive layer AF-D may each have an insulation property. The first adhesive layer AF-C and the second adhesive layer AF-D physically bond the circuit board CF and driver chip DC and the display panel DP, respectively.

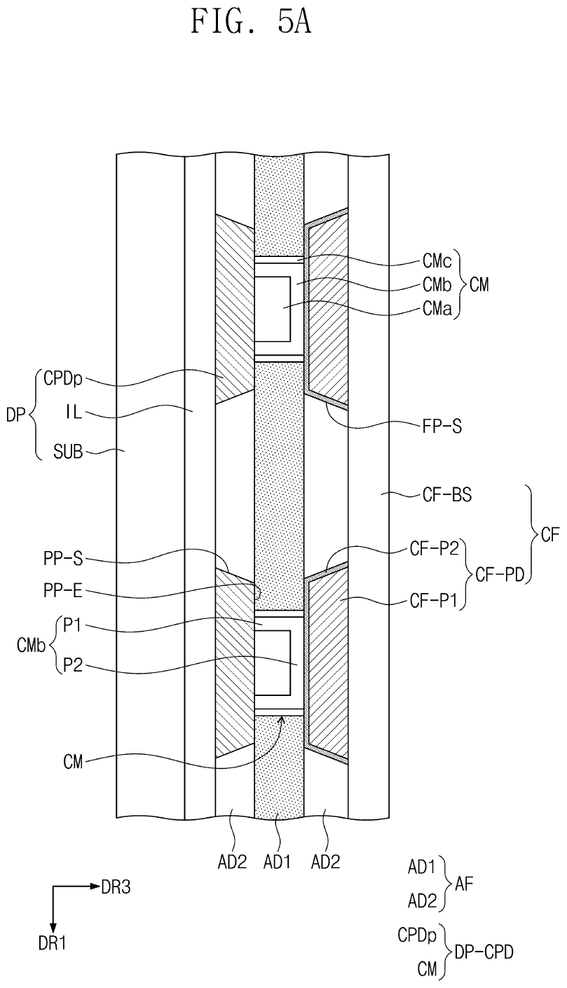

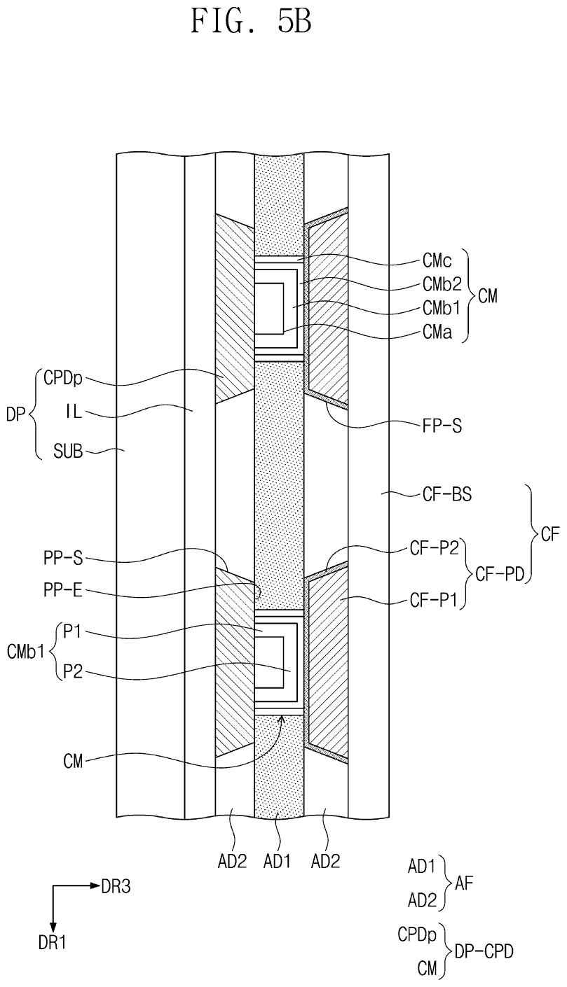

The circuit board CF may include an upper surface CF-US and a lower surface CF-DS. The lower surface CF-DS of the circuit board CF may be a surface facing the display panel DP. The circuit pads CF-PD may be disposed on the lower surface CF-DS of the circuit board CF and electrically connected to the second display pads DP-CPD of the display panel DP, respectively. The circuit pads CF-PD and the second display pads DP-CPD may be electrically connected to each other through a conductive member CM (see FIG. 5A) to be described later.

The driver chip DC may include an upper surface DC-US and a lower surface DC-DS. The lower surface DC-DS of the driver chip DC may be a surface facing the display panel DP. The driver chip DC may include chip pads DC-PD disposed on the lower surface DC-DS. The chip pads DC-PD may be electrically connected to the respective first display pads DP-PD disposed on the base substrate SUB.

The chip pads DC-PD include first-row chip pads DC-PD1 arranged in the first direction DR1 and second-row chip pads DC-PD2 spaced apart from the first-row chip pads DC-PD1 in the second direction DR2 and arranged in the first direction DR1. The first-row chip pads DC-PD1 and the second-row chip pads DC-PD2 may each have a shape exposed from the lower surface of the driver chip DC to the outside.

FIG. 4 illustrates that the chip pads DC-PD are arranged in two rows, but the chip pads DC-PD may be arranged in a single row or rows on the basis of a structure in which the first display pads DP-PD are arranged. The chip pads DC-PD and the first display pads DP-PD may be electrically connected to each other through a conductive member CM (see FIG. 5A) to be described later.

Hereinafter, the connection between the circuit board CF and the display panel DP is illustrated by way of example, but a later-described structure for connection between the circuit board CF and the display panel DP may be similarly applied to the connection between the driver chip DC and the display panel DP.

Also, hereinafter, the first pad DP-CPD may correspond to the aforementioned second display pads DP-CPD, and the second pad CF-PD may correspond to the aforementioned circuit pads CF-PD.

FIGS. 5A and 5B are schematic cross-sectional views of bonded pads of a display device according to an embodiment.

Referring to FIG. 5A, an insulating layer IL may be disposed between a base substrate SUB of a display panel DP and first pads DP-CPD. The insulating layer IL may be provided as a single layer or layers. The first pads DP-CPD may be formed by being branched from any one layer or a layer of conductive patterns disposed in the insulating layer IL and are not limited to any one embodiment. This is illustrated as an example. The first pads DP-CPD may be directly disposed on the base substrate SUB or have a two-layered structure in which two layers are connected while passing through the insulating layer IL, and are not limited to any one embodiment.

A circuit board CF may include a base layer CF-BS and second pads CF-PD disposed on the base layer CF-BS. The second pads CF-PD may include a first circuit pad CF-P1 and a second circuit pad CF-P2 covering the first circuit pad CF-P1. The second circuit pad CF-P2 may have a relatively smaller thickness than the first circuit pad CF-P1.

In this specification, the first circuit pad CF-P1 may include a material different from that of the second circuit pad CF-P2. The second circuit pad CF-P2 may include a material having a relatively lower electronegativity than the first circuit pad CF-P1 or a material having a high ionization tendency. For example, the first circuit pad CF-P1 may be made of copper, and the second circuit pad CF-P2 may be made of tin (Sn) having a relatively higher ionization tendency. Since the second circuit pad CF-P2 is more readily oxidized than the first circuit pad CF-P1, it is possible to prevent the first circuit pad CF-P1 from being oxidized.

However, an embodiment is not limited thereto. The second pads CF-PD included in a second substrate CF may be provided as a single layer or three or more layers, and are not limited to any one embodiment.

An adhesive layer AF may include a first resin layer AD1 and second resin layers AD2. The first resin layer AD1 and the second resin layers AD2 may physically bond the display panel DP and the circuit board CF.

The first resin layer AD1 may be disposed between the display panel DP and the circuit board CF. The first resin layer AD1 may be disposed between the second resin layers AD2. In this embodiment, the first resin layer AD1 may cover an upper surface PP-E of a pad part CPDp.

The second resin layer AD2 may be disposed between the first resin layer AD1 and the circuit board CF. The second resin layers AD2 may cover side surfaces PP-S of the first pads DP-CPD or side surfaces FP-S of the second pads CF-PD.

The first resin layer AD1 and the second resin layers AD2 according to the disclosure may be adhesive resins respectively including different initiators. For example, the first resin layer AD1 may include a photocuring agent, and the second resin layers AD2 may include a thermal curing agent. The first resin layer AD1 including a photoinitiator may be activated by ultraviolet light (UV), and the second resin layers AD2 including a thermal initiator may be activated by external heat. However, an embodiment is not limited thereto, and the first resin layer AD1 and the second resin layers AD2 may be adhesive resins including the same initiator.

In the drawing, it is illustrated that both the first resin layer AD1 and the second resin layers AD2 are present, but an embodiment is not limited thereto. Only one resin layer may be present, or the first resin layer AD1 and the second resin layers AD2 may each be a single resin layer, but it is not limited to any one embodiment.

First pads DP-CPD may each include a pad part CPDp and a conductive member CM. The pad part CPDp is connected to the corresponding signal line of the signal lines SGL (see FIG. 3), and the conductive member CM is connected to the pad part CPDp.

The conductive member CM may be disposed on the pad part CPDp. According to an embodiment, the conductive member CM may be disposed between the pad part CPDp and the second pad CF-PD and may be in direct contact with each of the pad part CPDp and the second pad CF-PD. The conductive member CM may be provided in plurality, and the number of the conductive member CM provided herein may correspond to the number of the pad parts CPDp and second pads CF-PD, and the conductive members CM may be disposed on one pad part CPDp. In one embodiment, a plurality of pad parts CPDp may be disposed in one direction, and a plurality of second pads CF-PD may also be disposed in the one direction. The first pad DP-CPD may be electrically connected to the second pad CF-PD through the conductive member CM.

The conductive member CM may include a first member CMa, a second member CMb, and a third member CMc.

The first member CMa may be disposed on the pad part CPDp. The first member CMa may have an insulation property. For example, the first member CMa may include a polymer, and is not limited to any one embodiment. The first member CMa may be disposed on an upper surface PP-E of the pad part CPDp.

The second member CMb may cover the first member CMa. The second member CMb may be disposed on the first member CMa and connected to the pad part CPDp. The second member CMb may have conductivity. For example, the second member CMb may include aluminum (Al) and is not limited to any one embodiment. The second member CMb may be in contact with the upper surface PP-E of the pad part CPDp.

The third member CMc may be disposed on the second member CMb. The third member CMc may partially cover the second member CMb. For example, the third member CMc exposes at least a portion of the second member CMb.

The third member CMc may include a material different from that of the second member CMb. The third member CMc may include a material having lower reactivity than the second member CMb. For example, the third member CMc may include a material having lower reactivity to oxygen than the second member CMb. For example, the third member CMc may include titanium (Ti) and is not limited to any one embodiment. The third member CMc prevents exposure of the second member CMb, so that the second member CMb may be prevented from being corroded due to oxygen.

Additionally, the third member CMc may be disposed between the second member CMb and the adhesive layer AF. For example, the third member CMc may prevent contact between the second member CMb and the adhesive layer AF.

According to an embodiment, the thickness of the third member CMc may be smaller than the thickness of the second member CMb. The thickness ratio of the second member CMb to the third member CMc may be about ⅙ or less. The third member CMc may have a thickness in a range of about 100 Å to about 400 Å, or of in a range of about 100 Å to about 300 Å.

The second member CMb may include a first portion P1 and a second portion P2. The first portion P1 may be covered by the third member CMc, and the second portion P2 may be exposed from the third member CMc. The second portion P2 of the second member CMb may be in direct contact with the second pad CF-PD.

The second member CMb may be connected to the pad part CPDp and in direct contact with the second pad CF-PD, so that the first pad DP-CPD and the second pad CF-PD may be electrically connected to each other.

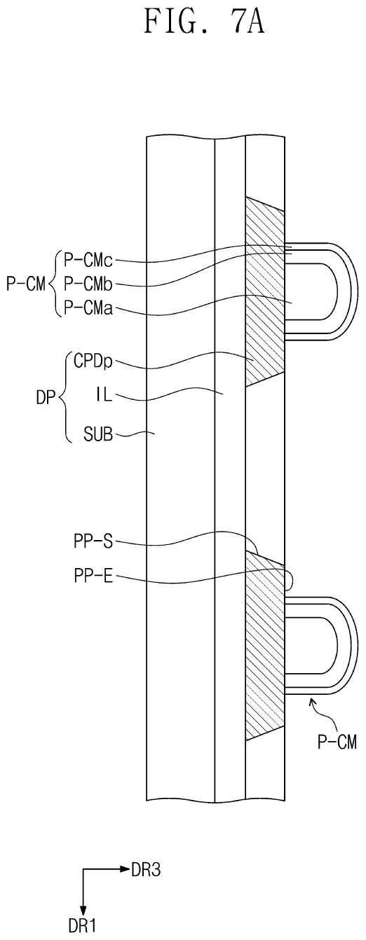

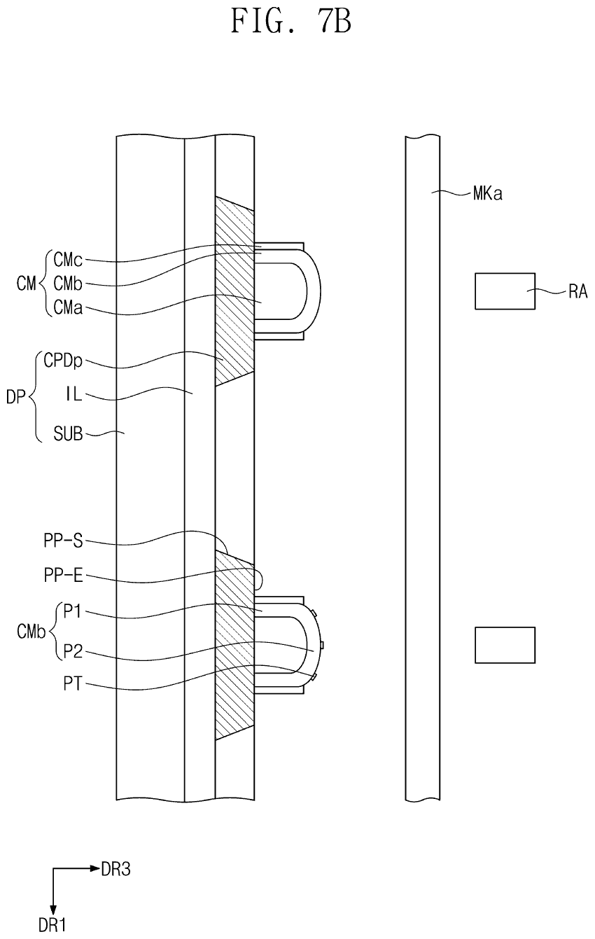

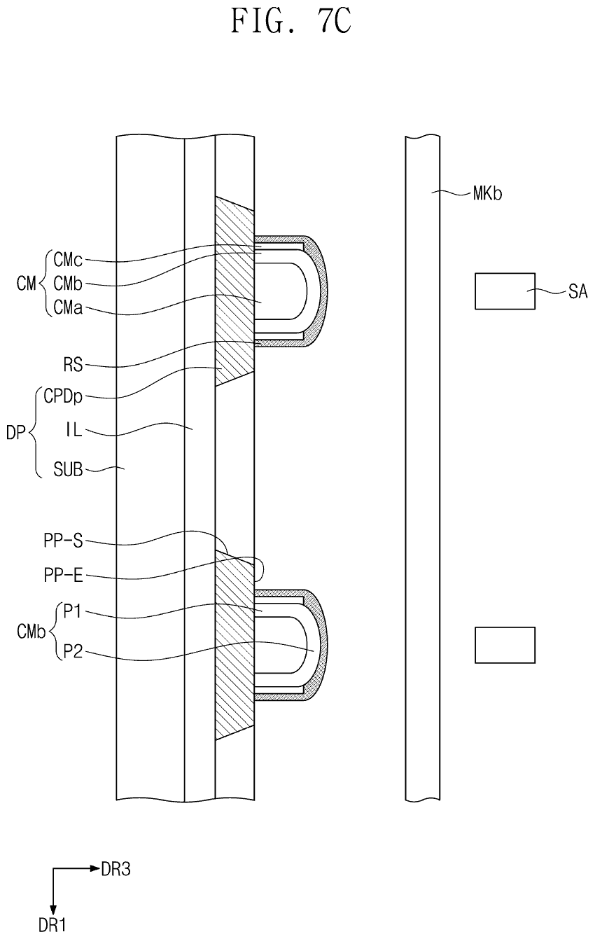

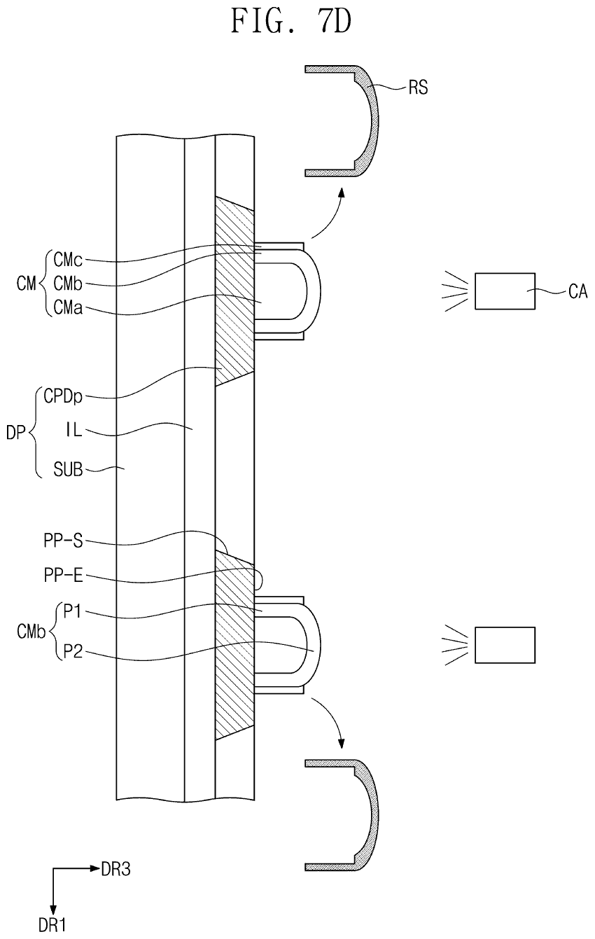

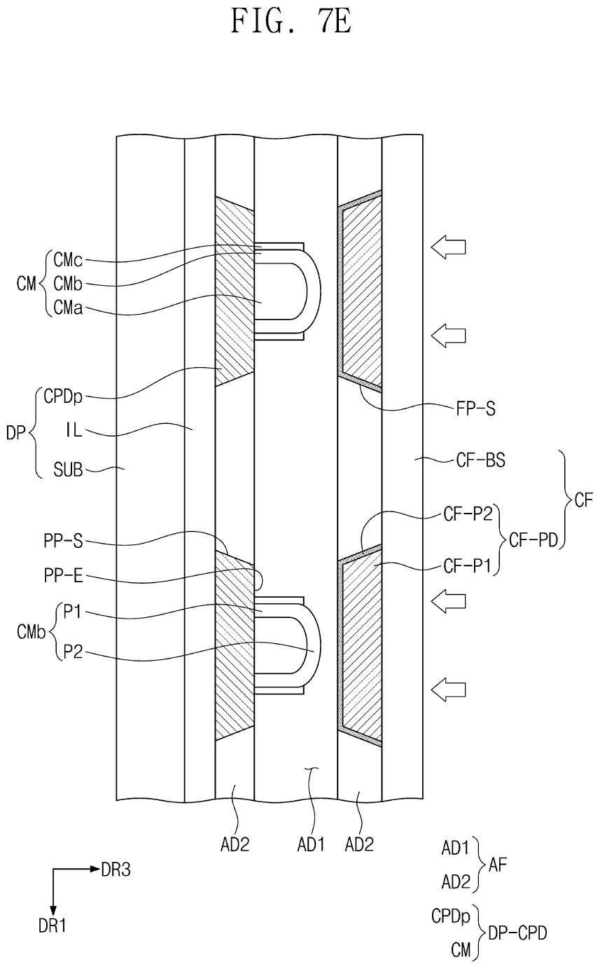

Although not illustrated in the drawing, patterns PT (see FIG. 7B) may be disposed on the second portion P2, and the patterns PT (see FIG. 7B) may include the same material or a similar material as the third member CMc. However, the patterns PT are not limited to any one embodiment.

Referring to FIG. 5B, the conductive member CM may include a sub member CMb2 disposed between the second member CMb1 and the third member CMc. The sub member CMb2 may be connected to the pad part CPDp and in contact with the upper surface PP-E of the pad part CPDp.

The sub member CMb2 may include a conductive material. The sub member CMb2 may be composed of a material different from that of the third member CMc. The sub member CMb2 may include the same material or a similar material as the second member CMb1, but is not limited thereto. The sub member CMb2 and the second member CMb1 may include different materials.

The connection structure for connection between the aforementioned circuit board CF (see FIG. 4) and display panel DP may be similarly applied to the connection between the driver chip DC (see FIG. 4) and the display panel DP.

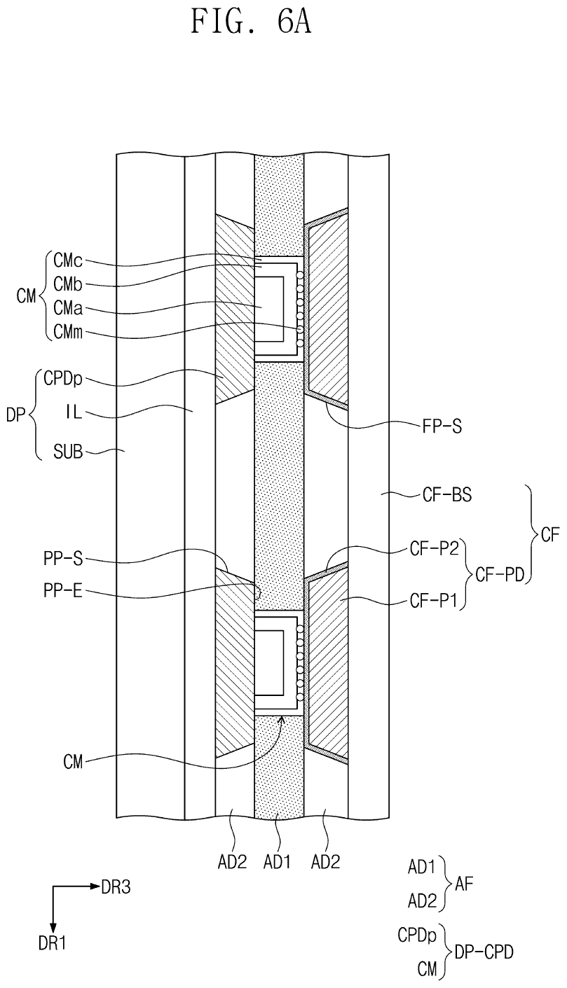

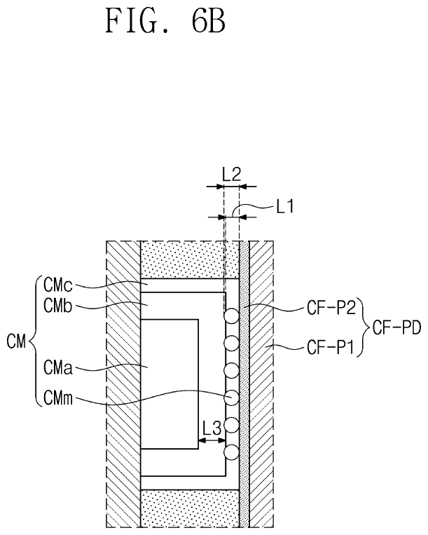

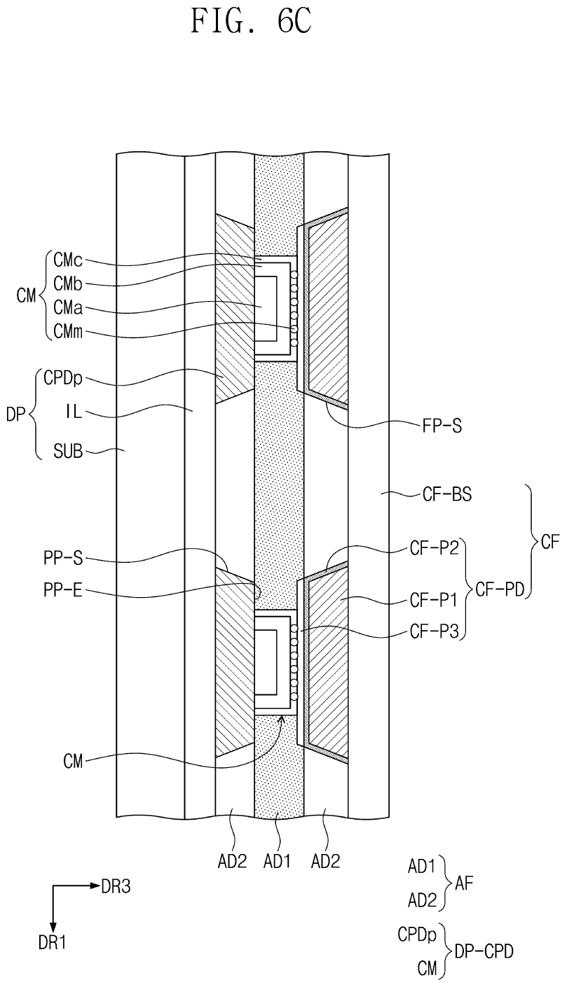

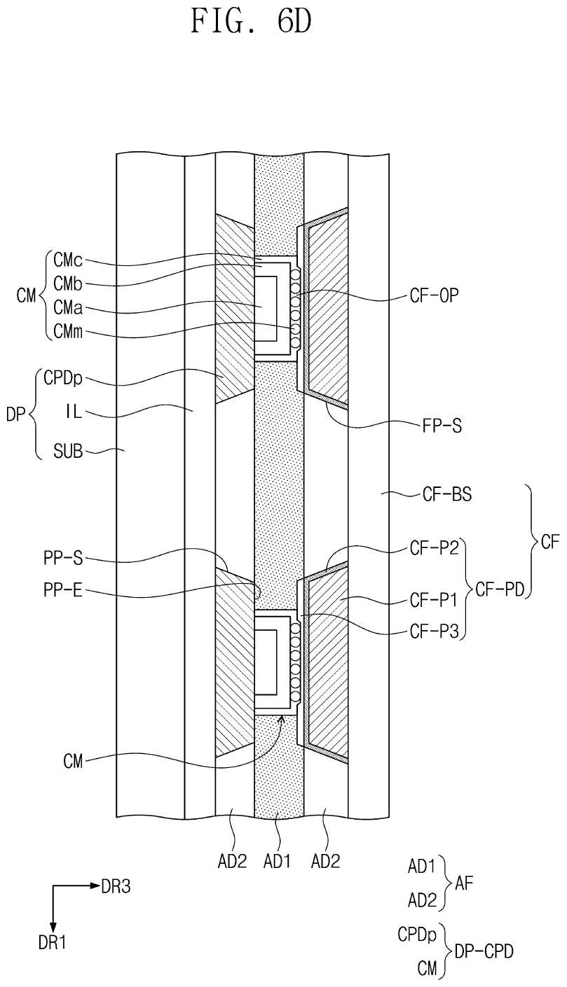

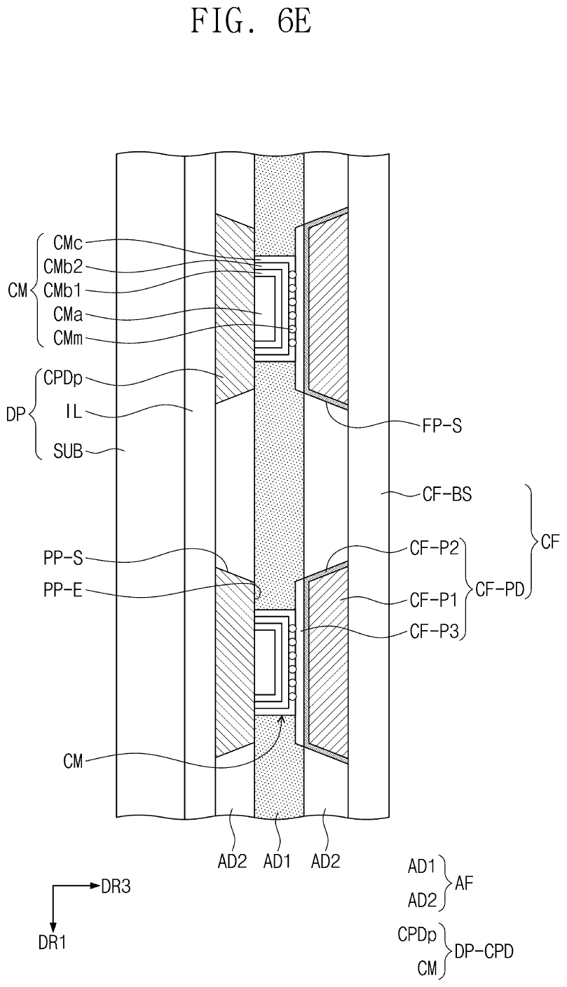

FIGS. 6A to 6E are schematic cross-sectional views of bonded pads of a display device according to an embodiment.

Hereinafter, the same reference numerals or symbols are used for the duplicated components of FIGS. 5A and 5B according to an embodiment, and a description thereof will be omitted.

Referring to FIGS. 6A and 6B, a conductive member CM may include a first member CMa, a second member CMb, a third member CMc, and conductive particles CMm.

The conductive particles CMm may electrically connect the second member CMb to the second pad CF-PD. According to an embodiment, the conductive particles CMm may overlap the third member CMc on a plane. The conductive particles CMm may pass through the third member CMc, a portion of the conductive particles CMm may be in direct contact with the second member CMb, and another portion of the conductive particles CMm may be in direct contact with the second pad CF-PD. The conductive particles CMm may pass through the third member CMc and be fixed inside the third member CMc, thereby securing the reliability of the electrical connection between the first pad DP-CPD and the second pad CF-PD.

The conductive particles CMm may each include a conductive material and include a metal material. However, an embodiment is not limited thereto, and the conductive particles CMm may include other conductive materials.

The conductive particles CMm may overlap the pad part CPDp on a plane and also may overlap the second pad CF-PD on a plane. Since the conductive particles CMm are not disposed in a region where the conductive particles CMm do not overlap the pad part CPDp or the second pad CF-PD, unpredictable short-circuiting, etc., between the first pad DP-CPD and the second pad CF-PD may be prevented and thus the reliability of the electrical connection between the first pad DP-CPD and the second pad CF-PD may be secured.

The third member CMc or the second pad CF-PD may each include a curable material. The third member CMc or the second pad CF-PD are cured in a state in which the conductive particles CMm are in contact therewith, and thus the conductive particles CMm may be prevented from positional deviation. Thus, the reliability of the electrical connection between the first pad DP-CPD and the second pad CF-PD may be secured.

According to an embodiment, the thickness L1 of the third member CMc may be smaller than the thickness L3 of the second member CMb. The second member CMb may have a thickness L3 in a range of about 2500 Å to about 7000 Å, and the third member CMc may have a thickness L1 in a range of about 100 Å to about 400 Å.

According to an embodiment, the ratio of the thickness L1 of the third member CMc to the thickness L3 of the second member CMb may be about ⅙ or less. For example, the second member CMb may have a thickness L3 of about 2500 Å, and the third member CMc may have a thickness L1 of about 400 Å.

By way of example, according to an embodiment, the ratio of the thickness L1 of the third member CMc to the thickness L3 of the second member CMb may be about 1/20 or less. For example, the second member CMb may have a thickness L3 of about 6000 Å, and the third member CMc may have a thickness L1 of about 300 Å.

The third member CMc may have a thickness L1 in a range of about 100 Å to about 400 Å or in a range of about 100 Å to about 300 Å. The thickness L1 of the third member CMc may be reduced to improve the reliability of the electrical connection between the first pad DP-CPD and the second pad CF-PD.

According to an embodiment, in case that the second member CMb has a thickness L3 of about 6000 Å, and the third member CMc has a thickness L1 of about 300 Å, the contact resistance between the first pad DP-CPD and the second pad CF-PD may be about 8.39 Ω. In case that the second member CMb has a thickness L3 of about 6000 Å, and the third member CMc has a thickness L1 of about 100 Å, the contact resistance between the first pad DP-CPD and the second pad CF-PD may be about 0.49 Ω.

Since the third member CMc having a thickness L1 in a range of about 100 Å to about 400 Å is provided, the contact resistance between the first pad DP-CPD and the second pad CF-PD is reduced and thus the reliability of the electrical connection between each of the pads DP-CPD and CF-PD may be secured. In case that the third member CMc may have a thickness L1 in a range of about 250 Å to about 350 Å, the reliability of the electrical connection between the pads DP-CPD and CF-PD may be further improved. By way of example, the third member CMc may have a thickness L1 of about 300 Å.

This may be similarly applied to the aforementioned embodiments of FIGS. 5A and 5B.

The third member CMc may have a thickness L1 smaller than or equal to the minimum diameter of the conductive particles CMm. Since the diameter of the conductive particles CMm is greater than or equal to the thickness L1 of the third member CMc, the third member CMc may be in direct contact with both the second member CMb and the second pad CF-PD and thus the reliability of the electrical connection between the pads DP-CPD and CF-PD may be secured.

Referring to FIG. 6C, a sub pad CF-P3 covering the second pad CF-PD may be further included. The sub pad CF-P3 may be in direct contact with the second pad CF-PD.

The sub pad CF-P3 may be in contact with the conductive particles CMm. According to an embodiment, the sub pad CF-P3 may be in direct contact with the conductive particles CMm. The sub pad CF-P3 may be in contact with the third member CMc.

According to an embodiment, the conductive particles CMm may pass through a portion of the sub pad CF-P3. The conductive particles CMm may pass through a portion of the sub pad CF-P3 and be fixed on the sub pad CF-P3, thereby ensuring the reliability of the electrical connection between each of pads PD-CPD and CF-PD.

The sub pad CF-P3 may include a conductive material. For example, the sub pad may include silver (Ag, antigen) and is not limited to any one embodiment. The sub pad CF-P3 may include a curable material. The sub pad CF-P3 is cured in a state in which the conductive particles CMm are in contact with or pass through the sub pad CF-P3, and thus the conductive particles CMm may be prevented from positional deviation.

Referring to FIG. 6D, the sub pad CF-P3 may include a recessed portion CF-OP. The recessed portion CF-OP may be recessed in the third direction DR3, but is not limited thereto. The recessed portion CF-OP may be formed as an opening. The recessed portion CF-OP may accommodate the conductive particles CMm and prevent the positional deviation of the conductive particles CMm.

Referring to FIG. 6E, the conductive member CM may include a sub member CMb2 disposed between the second member CMb1 and the third member CMc. The sub member CMb2 may be connected to the first pad DP-CPD and in contact with an upper surface PP-E of the pad part CPDp.

The sub member CMb2 may include a conductive material. The sub member CMb2 may be composed of a material different from that of the third member CMc. The sub member CMb2 may include the same material or a similar material as the second member CMb1, but is not limited thereto. The sub member CMb2 may include different materials.

FIGS. 7A to 7E are schematic cross-sectional views illustrating a number of operations of a method of manufacturing an electronic device according to an embodiment.

Referring to FIGS. 7A to 7E, the method of manufacturing the electronic device according to an embodiment may include preparing a display panel DP including a first pad DP-CPD including a pad part CPDp and a preliminary conductive member P-CM, forming a conductive member CM from the preliminary conductive member P-CM, covering the conductive member CM with a resin RS, removing the resin RS that covers the conductive member CM, and electrically connecting a circuit board CF to the display panel DP.

Referring to FIG. 7A, the display panel DP, which is prepared in the preparing of the display panel DP including the first pad DP-CPD including the pad part CPDp and the preliminary conductive member P-CM, may correspond to the aforementioned display panel DP (see FIG. 5A). The preliminary conductive member P-CM may have a stacked structure of layers. The preliminary conductive member P-CM may include a first member P-CMa, a second member P-CMb, and a third member P-CMc. Although not illustrated in the drawing, a sub member may be disposed between the second member P-CMb and the third member P-CMc.

The first member P-CMa corresponds to the aforementioned first member CMa (see FIG. 5A), and the second member P-CMb corresponds to the aforementioned second member CMb (see FIG. 5A). The third member P-CMc differs from the aforementioned third member CMc (see FIG. 5A) in that the third member P-CMc fully covers the second member P-CMb.

As an embodiment, the preliminary conductive member P-CM having a stacked structure may be formed on the display panel DP.

Hereinafter, for convenience of description, the same reference numerals or symbols are used for the duplicated components described above, and the detailed description thereof will be omitted.

Referring to FIG. 7B, in the forming of the conductive member CM from the preliminary conductive member P-CM (see FIG. 7A), a portion of the third member P-CMc (see FIG. 7A) may be removed and a portion of the second member CMb may be exposed. For example, it is understood that the preliminary conductive member P-CM (see FIG. 7A) is a member in a state where a portion of the third member P-CMc (see FIG. 7A) is not removed, and the conductive member CM is a member in a state where a portion of the third member CMc is removed and a portion of the second member CMb is exposed.

The second member CMb of the conductive member CM may include a first portion P1 and a second portion P2. As described above, the first portion P1 is a portion covered by the third member CMc, and the second portion P2 is a portion which is not covered by the third member CMc and corresponds to an exposed portion.

Referring to the drawing, in the forming of the conductive member CM from the preliminary conductive member P-CM according to an embodiment, a portion of the third member P-CMc (see FIG. 7A) may be removed by using a mask MKa and a third member removal apparatus RA. However, the forming of the conductive member CM is not limited to what is illustrated in the drawing, the mask may be omitted, and the forming of the conductive member CM is not limited to any one embodiment. In the drawing, an opening of the mask MKa is omitted, and an embodiment is not limited thereto.

Patterns PT may be disposed on the second portion P2. The patterns PT may include the same material or a similar material as the third member CMc, but are not limited thereto. The patterns PT may include different materials.

According to an embodiment, the pattern PT may be a section where a portion of the third member P-CMc (see FIG. 7A) is not removed, but is not limited thereto.

As illustrated in the drawing, the patterns PT may be present only in some or a number of the conductive members CM, but are not limited to what is illustrated in the drawing. The patterns PT may be present in all of the conductive members CM, but an embodiment is not limited thereto. The patterns PT may not be present in all of the conductive members CM, and are not limited to any one embodiment.

A portion of the third member P-CMc (see FIG. 7A) is removed in advance before a later-described operation of electrically connecting a circuit board CF (see FIG. 7E) to the display panel DP, so that the second member CMb and the second pad CF-PD may be prevented from not being in direct contact with each other due to the third member CMc. Thus, poor electrical connection between the second member CMb and the second pad CF-PD (see FIG. 5A) may be prevented. For example, it is possible to prevent an increase in bonding resistance, which may occur due to poor electrical connection between the first pad DP-CPD (see FIG. 5A) and the second pad CF-PD (see FIG. 5A). For example, since a portion of the third member P-CMc (see FIG. 7A) is removed in advance, abnormal driving of an electronic device is prevented to secure driving reliability and thus high-resolution driving may be stabilized.

Referring to FIG. 7C, in the covering of the conductive member CM with a resin RS, the resin RS may cover the second member CMb and the third member CMc of the conductive member CM. According to an embodiment, the resin RS may be applied to the third member CMc which is not removed, and the second member CMb which is not covered by the third member CMc and exposed. For example, the resin RS may be applied to the third member CMc and the second portion P2 of the second member CMb. The resin is applied to the third member CMc and the second portion P2 of the second member CMb, and therefore the first portion P1 and the second portion P2 may be effectively prevented from being corroded.

In the drawing, the case where the aforementioned pattern PT (see FIG. 7B) is absent on the second portion P2 is illustrated, but an embodiment is not limited thereto. The resin RS may also be sprayed even in the case where the pattern PT (see FIG. 7B) is present on the second portion P2, and the disclosure is not limited to any one embodiment.

During the whole processes, in moving or additional processing of the display panel DP, the first portion P1 and the second portion P2 may be effectively prevented from being corroded until the applied resin RS is removed.

Additionally, the first portion P1 is further covered by the resin RS together with the third member CMc, so that the first portion P1 may be effectively prevented from being corroded.

Referring to the drawing, in an embodiment, the resin RS may be applied to the conductive member CM by using a mask MKb and a sprayer SA in a process of covering the conductive member CM with the resin RS. However, the spraying of the resin RS is not limited to what is illustrated in the drawing, and the mask MKb may be omitted. The resin RS may be applied to the entire region of the display panel DP without being limited to a region where the conductive member CM is disposed, and the disclosure is not limited to any one embodiment.

Referring to FIG. 7D, in the removing of the resin RS covering the conductive member CM, the resin RS covering the conductive member CM or the display panel DP may be removed by using a resin removal apparatus CA. Referring to the drawing, according to an embodiment, the resin RS may be removed while maintaining a circular shape, but it is not limited thereto. The resin RS may be removed while changing in shape, and the disclosure is not limited to any one embodiment.

The removing of the resin RS covering the conductive member CM may be performed immediately before electrically connecting, to the circuit board CF (see FIG. 7E), the display panel DP including the conductive member CM to which the resin RS is applied or the display panel DP to which the resin RS is applied. Thus, during the whole processes, in moving or additional processing of the display panel DP from which the applied resin RS is not removed, the second member CMb may be effectively prevented from being corroded.

Referring to FIG. 7E, in the electrically connecting of the circuit board CF to the display panel DP, the first pad DP-CPD and the second pad CF-PD may be electrically connected to each other. As illustrated in the drawing, the circuit board CF and the display panel DP may be electrically connected to each other by pressurizing the circuit board CF toward the display panel DP, and an embodiment is not limited to what is illustrated in the drawing. The circuit board CF and the display panel DP may be electrically connected to each other by pressurizing the display panel DP toward the circuit board CF, and the disclosure is not limited to any one embodiment.

According to an embodiment, the method may include, before the electrically connecting of the first pad DP-CPD to the second pad CF-PD, forming an adhesive layer AF on the display panel DP. However, the adhesive layer AF is formed not only on the display panel DP, but also on the circuit board CF. The forming of the adhesive layer AF is not limited to any one embodiment.

The adhesive layer AF may have an insulation property, and physically bonds each of the circuit board CF and the display panel DP. For example, the adhesive layer AF may be a non-conductive film (NCF).

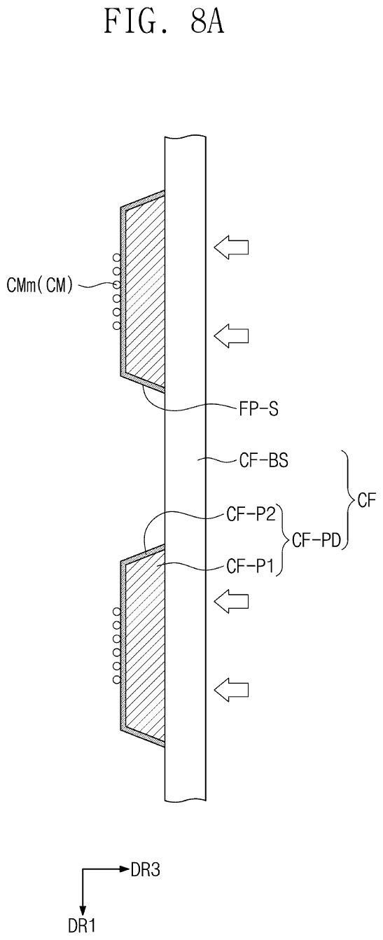

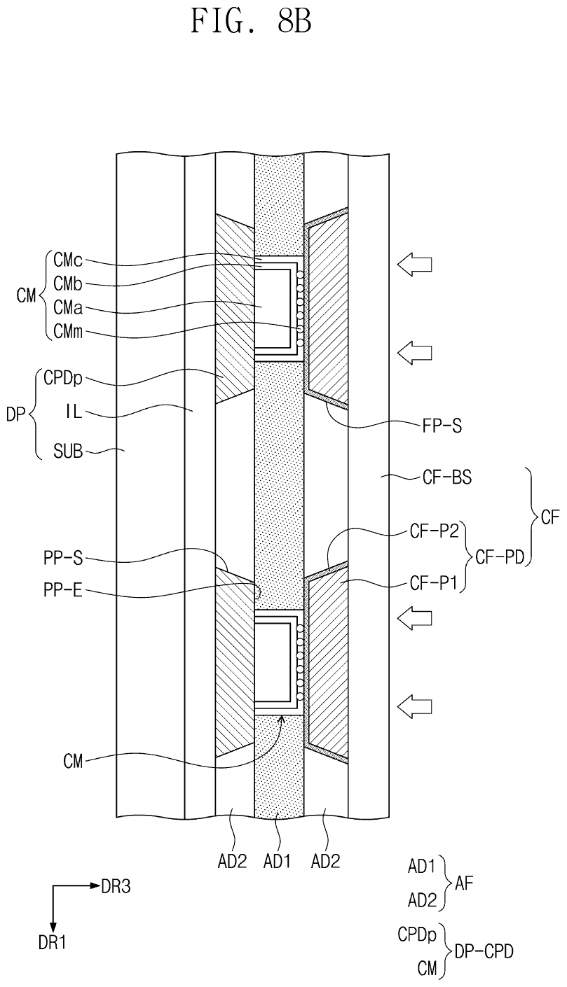

FIGS. 8A and 8B are schematic cross-sectional views illustrating a number of operations of a method of manufacturing an electronic device according to an embodiment.

Referring to FIGS. 8A and 8B, the method of manufacturing the electronic device according to an embodiment may include preparing an adhesive layer AF, a circuit board CF, and a display panel DP including a first pad part DP-CPD including a pad part CPDp and a conductive member CM, and electrically connecting the circuit board CF to the display panel DP.

The display panel DP, the circuit board CF, the conductive member CM, and the adhesive layer AF, which are illustrated in FIGS. 8A and 8B, may respectively correspond to the display panel DP (see FIG. 6A), the circuit board CF (see FIG. 6A), the conductive member CM (see FIG. 6A), and the adhesive layer AF (see FIG. 6A) which have been described above.

Referring to FIG. 8A, in the preparing of the circuit board CF and the display panel DP (see FIG. 8B) including the conductive member CM (see FIG. 8B), conductive particles CMm of the conductive member CM may be attached to a second pad CF-PD of the circuit board CF.

By pressurizing the circuit board CF toward the conductive particles CMm, the conductive particles CMm may be fixed while being in contact with the second pad CF-PD. This then makes it possible to prevent the conductive particles CMm from deviating from an initial position in case that the display panel DP (see FIG. 8B) and the circuit board CF are electrically connected to each other. The conductive particles CMm are prevented from being deviated and thus the reliability of the electrical connection between the display panel DP (see FIG. 8B) and the circuit board CF may be secured.

The drawing illustrates that the conductive particles CMm are attached to only a portion of the second pad CF-PD. However, an embodiment is not limited thereto, and the conductive particles CMm may be evenly attached to the entire region of the second pad CF-PD.

Referring to FIG. 8B, in the electrically connecting of the circuit board CF to the display panel DP, the first pad DP-CPD and the second pad CF-PD may be electrically connected to each other through the conductive member CM. The conductive particles CMm pass through the third member CMc to be in contact with each of the second member CMb and the second pad CF-PD and thus the reliability of the electrical connection therebetween may be secured.

The drawing illustrates that the circuit board CF and the display panel DP are electrically connected to each other by pressurizing the circuit board CF toward the display panel DP. However, an embodiment is not limited thereto, and the circuit board CF and the display panel DP may be electrically connected to each other by pressurizing the display panel DP toward the circuit board CF.

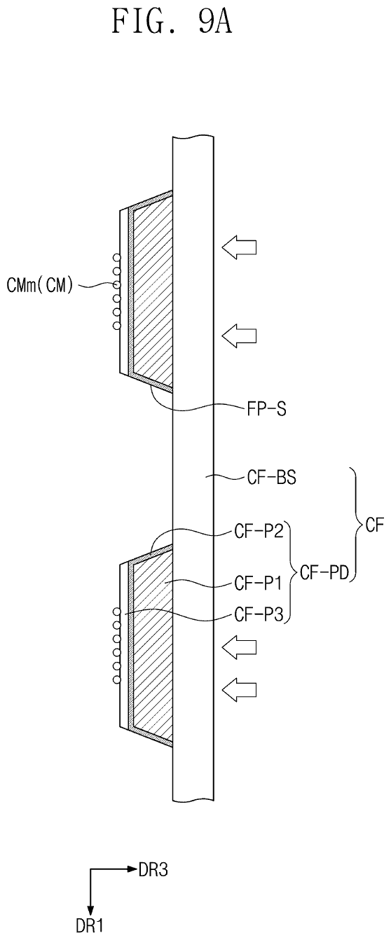

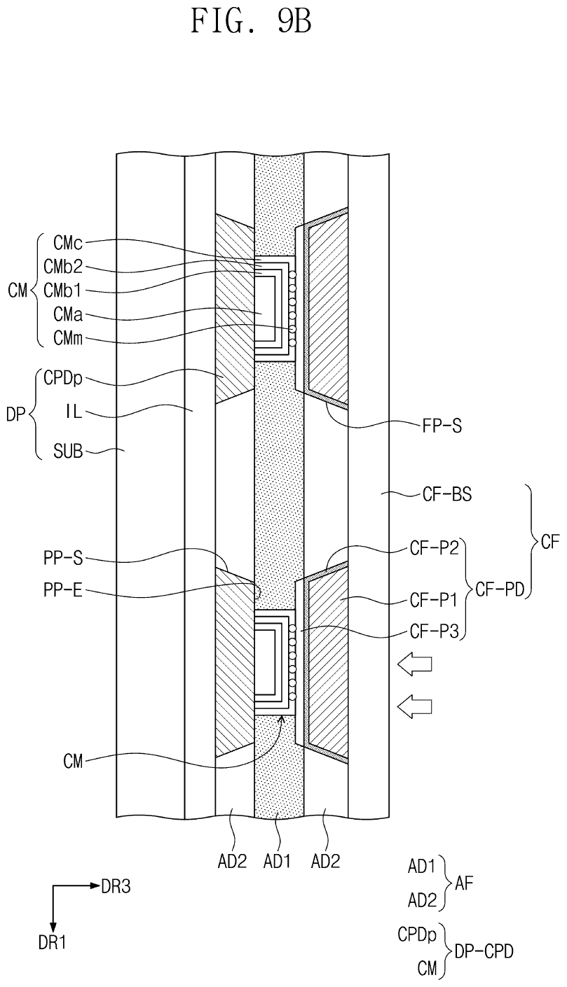

FIGS. 9A and 9B are schematic cross-sectional views illustrating a number of operations of a method of manufacturing an electronic device according to an embodiment.

For ease of description, the same reference numerals or symbols are used for the duplicated components described in FIGS. 8A and 8B, and the detailed description thereof will be omitted.

Referring to FIG. 9A, conductive particles CMm of a conductive member CM may be attached to a sub pad CF-P3 of a circuit board CF.

The sub pad CF-P3 may be attached to a second circuit pad CF-P2 through printing or coating, but is not limited thereto. The sub pad CF-P3 may be attached to the second circuit pad CF-P2 in various manners.

By pressurizing the circuit board CF toward the conductive particles CMm, the conductive particles CMm may be fixed while being in contact with the sub pad CF-P3. Thus, it is possible to prevent the conductive particles CMm from deviating from an initial position.

The drawing illustrates that the conductive particles CMm are attached to a portion of the sub pad CF-P3. However, an embodiment is not limited thereto, and the conductive particles CMm may be evenly attached to the entire region of the sub pad CF-P3.

Referring to FIG. 9B, in the electrically connecting of the circuit board CF to a display panel DP, a first pad DP-CPD and a second pad CF-PD may be electrically connected to each other through the conductive member CM. The conductive particles CMm pass through a third member CMc to be in contact with each of a second member CMb and the sub pad CF-P3 and thus the reliability of the electrical connection therebetween may be secured.

An electronic device and a method of manufacturing an electronic device according to an embodiment may provide an electronic device with improved electrical bonding reliability.

Although embodiments have been described, it is understood that the disclosure should not be limited to these embodiments but various changes and modifications can be made by one of ordinary skill in the art within the spirit and scope of the disclosure as hereinafter claimed. Therefore, the technical scope of the disclosure is not limited to the contents described in the detailed description of the specification, but should also be determined by the claims.

What is claimed is:

1. An electronic device comprising:
a display panel including:
a plurality of pixels;
a plurality of first pads respectively including pad parts which are disposed in one direction and respectively electrically connected to the pixels; and
conductive members electrically connected to the pad parts;
a circuit board including a plurality of second pads disposed in the one direction and respectively electrically connected to the first pads; and
an adhesive layer disposed between the display panel and the circuit board,
wherein the conductive members each include:
a first member disposed on the pad part and having an insulation property,
a second member covering the first member and connected to the pad parts, and
a third member disposed on the second member, exposing a portion of the second member and including a material different from a material of the second member.

2. The electronic device of claim 1, wherein
the second member comprises a first portion covered by the third member, and a second portion exposed from the third member, and
the second portion directly contacts the second pads.

3. The electronic device of claim 1, wherein the third member is disposed between the adhesive layer and the second member.

4. The electronic device of claim 1, wherein
a thickness of the third member is less than a thickness of the second member, and
a thickness ratio of the third member to the second member is about ⅙ or less.

5. The electronic device of claim 1, wherein the third member has a thickness in a range of about 100 Å to about 400 Å.

6. The electronic device of claim 1, wherein each of the conductive members comprises a sub member disposed between the second member and the third member.

7. The electronic device of claim 2, further comprising:
at least one pattern disposed on the second portion of the second member.

8. An electronic device comprising:
a display panel including:
a plurality of pixels;
a plurality of first pads respectively including pad parts which are disposed in one direction and respectively electrically connected to the pixels; and
conductive members electrically connected to the pad parts;
a circuit board including a plurality of second pads disposed in the one direction and respectively electrically connected to the first pads; and
an adhesive layer disposed between the display panel and the circuit board,
wherein the conductive members each include:
a first member disposed on the pad part and having an insulation property;
a second member covering the first member and connected to the pad part;
a third member disposed on the second member and including a material different from a material of the second member; and
a plurality of conductive particles electrically connecting the second pads to the second member while overlapping the third member in a plan view, and
a portion of at least one of the conductive particles passes through the third member and directly contacts the second member.

9. The electronic device of claim 8, further comprising:
a sub pad covering the second pads and contacting each of the second pads and the conductive particles.

10. The electronic device of claim 9, wherein another portion of at least one of the conductive particles passes through the sub pad.

11. The electronic device of claim 9, wherein the sub pad comprises a curable material.

12. The electronic device of claim 9, wherein the sub pad has a recessed portion accommodating the conductive particles.

13. The electronic device of claim 8, wherein a minimum diameter of the conductive particles is greater than a thickness of the third member.

14. The electronic device of claim 8, wherein
a thickness of the third member is less than a thickness of the second member, and
a thickness ratio of the third member to the second member is about ⅙ or less.

15. The electronic device of claim 8, wherein the third member has a thickness in a range of about 100 Å to about 400 Å.

16. The electronic device of claim 8, wherein the conductive member comprises a sub member disposed between the second member and the third member.

17. A method of manufacturing an electronic device, the method comprising:
preparing a display panel provided with a plurality of first pads including a pad part and a preliminary conductive member provided with a first member disposed on the pad part and having an insulation property, a second member covering the first member and connected to the pad part, and a third member disposed on the second member and including a material different from a material of the second member;
forming a conductive member from the preliminary conductive member in which a portion of the second member is exposed by removing a portion of the third member;
covering the conductive member with a resin by spraying the resin to the conductive member;
preparing a circuit board including a plurality of second pads respectively connected to the first pads and removing the resin covering the conductive member; and
electrically connecting the first pads to the second pads by pressurizing either of the circuit board and the display panel.

18. The method of claim 17, further comprising:
forming an adhesive layer on the display panel before the electrically connecting of the first pads to the second pads.

19. The method of claim 18, wherein
the second member comprises a first portion covered by the third member, and a second portion exposed from the third member, and
the second portion directly contacts the second pad.

20. The method of claim 19, wherein the conductive member further comprises:
at least one pattern disposed on the second portion of the second member.
